(19) United States
(12) Patent Application Publication
(10) Pub. No.: US 2026/0206301 A1
(43) Pub. Date: Jul. 16, 2026

(54) SEMICONDUCTOR DEVICE

(71) Applicant: SAMSUNG ELECTRONICS CO., LTD., Suwon-si (KR)

(72) Inventors: Sangwoo Han, Suwon-si (KR); Kyuman Hwang, Suwon-si (KR); Sungil Park, Suwon-si (KR); Jae Hyun Park, Suwon-si (KR); Juhun Park, Suwon-si (KR); Daewon Ha, Suwon-si (KR)

(73) Assignee: SAMSUNG ELECTRONICS CO., LTD., Suwon-si (KR)

(21) Appl. No.: 19/281,086

(22) Filed: Jul. 25, 2025

(30) Foreign Application Priority Data
Jan. 15, 2025 (KR) 10-2025-0005934

(51) Int. Cl. H10D 84/83; H01L 23/522; H01L 23/528; H10D 30/00; H10D 30/01; H10D 30/43; H10D 62/10; H10D 62/13; H10D 64/23; H10D 84/01

(52) U.S. Cl. CPC H10D 84/832; H10D 30/43; H10D 30/502; H10D 62/115; H10D 62/121; H10D 62/151; H10D 64/256; H10W 20/42; H10W 20/43; H10W 20/435; H10D 30/014; H10D 30/019; H10D 84/0149

(57) ABSTRACT

A semiconductor device may include lower sheet patterns spaced apart from each other in a first direction, a lower gate electrode surrounding the lower sheet patterns and extending in a second direction intersecting with the first direction, upper sheet patterns disposed on the lower gate electrode and spaced apart from each other in the first direction, an upper gate electrode on the lower gate electrode, the upper gate electrode surrounding the upper sheet patterns and extending in the second direction, and an upper isolation layer penetrating an upper surface of the upper gate electrode and extending in the first direction. The upper isolation layer penetrates a portion of the upper sheet patterns.

### CROSS-REFERENCE TO RELATED APPLICATION

This application claims priority to Korean Patent Application No. 10-2025-0005934, filed in the Korean Intellectual Property Office on Jan. 15, 2025, the entire contents of which being hereby incorporated by reference.

### BACKGROUND

The present disclosure relates to semiconductor devices.

Semiconductor elements are core components used to control or amplify electrical signals in electronic devices, and various types of semiconductor elements may be manufactured. For example, memory elements may be used mainly to store and retrieve data, and non-memory elements may be used to control or amplify electrical signals. Semiconductor elements serve as core components of electronic devices, playing important roles in diverse fields such as computers, communication equipment, and consumer electronics.

With industrial development, demands for the performance and functionality of electronic devices continue to increase. Accordingly, high-performance characteristics of semiconductor elements are now essential, and in order to meet these demands, the level of integration of semiconductor elements is increasing. Various methods for forming semiconductor elements having excellent performance and enhanced integration are under study.

### SUMMARY OF THE INVENTION

It is an aspect to provide a semiconductor device with improved electrical characteristics and reliability.

It is another aspect to provide a method of manufacturing a semiconductor device with improved electrical characteristics and reliability.

According to an aspect of one or more embodiments, there is provided a semiconductor device may include a plurality of lower sheet patterns spaced apart from each other in a first direction, a lower gate electrode surrounding the plurality of lower sheet patterns and extending in a second direction intersecting with the first direction, a plurality of upper sheet patterns disposed on the lower gate electrode and spaced apart from each other in the first direction, an upper gate electrode disposed on the lower gate electrode and surrounding the plurality of upper sheet patterns, the upper gate electrode extending in the second direction, and an upper isolation layer penetrating an upper surface of the upper gate electrode and extending in the first direction, wherein the upper isolation layer penetrates at least a portion of the plurality of upper sheet patterns.

According to another aspect of one or more embodiments, there is provided a semiconductor device comprising a lower wiring insulating layer; a lower wiring structure in the lower wiring insulating layer; a plurality of lower sheet patterns disposed on the lower wiring insulating layer and spaced apart from each other in a first direction; a lower gate electrode surrounding the plurality of lower sheet patterns and extending in a second direction intersecting the first direction; a lower source/drain pattern on at least one side of the plurality of lower sheet patterns; a lower isolation layer on the lower wiring insulating layer, the lower isolation layer penetrating a lower surface of the lower gate electrode and extending in the first direction; a plurality of upper sheet patterns disposed on the lower gate electrode and spaced apart from each other in the first direction; an upper gate electrode on the lower gate electrode, the upper gate electrode surrounding the plurality of upper sheet patterns and extending in the second direction; an upper source/drain pattern on at least one side of the plurality of upper sheet patterns; and an upper isolation layer penetrating an upper surface of the upper gate electrode and extending in the first direction. The lower isolation layer penetrates at least a portion of the plurality of lower sheet patterns, and the upper isolation layer penetrates at least a portion of the plurality of upper sheet patterns.

According to yet another aspect of one or more embodiments, there is provided a semiconductor device comprising a lower wiring insulating layer; a lower wiring structure in the lower wiring insulating layer; a plurality of lower sheet patterns disposed on the lower wiring insulating layer and spaced apart from each other in a first direction; a lower gate electrode surrounding the plurality of lower sheet patterns and extending in a second direction intersecting the first direction; a lower gate contact disposed on the lower gate electrode and penetrating the lower wiring insulating layer; a lower source/drain pattern on at least one side of the plurality of lower sheet patterns; a lower isolation layer on the lower wiring insulating layer, the lower isolation layer penetrating a lower surface of the lower gate electrode and extending in the first direction; a plurality of upper sheet patterns disposed on the lower gate electrode and spaced apart from each other in the first direction; an upper gate electrode on the lower gate electrode, the upper gate electrode surrounding the plurality of upper sheet patterns and extending in the second direction; a gate capping pattern on an upper surface of the upper gate electrode; an upper source/drain pattern on at least one side of the plurality of upper sheet patterns; and an upper isolation layer penetrating the upper surface of the upper gate electrode and extending in the first direction. The lower isolation layer penetrates at least a portion of the plurality of lower sheet patterns, the upper isolation layer penetrates the gate capping pattern and at least a portion of the plurality of upper sheet patterns, and the upper isolation layer overlaps the lower isolation layer in the first direction.

According to still aspect of one or more embodiments, there is provided a semiconductor device manufacturing method including forming a lower pattern, a plurality of lower sheet patterns, and a plurality of upper sheet patterns on a substrate, each of the plurality of lower sheet patterns being spaced apart in a first direction, and each of the plurality of upper sheet patterns being spaced apart in the first direction; forming a lower source/drain pattern on at least one side of each of the plurality of lower sheet patterns; forming an upper source/drain pattern on at least one side of each of the plurality of upper sheet patterns; forming a lower gate electrode surrounding the plurality of lower sheet patterns and extending in a second direction intersecting the first direction; forming an upper gate electrode surrounding the plurality of upper sheet patterns and extending in the second direction; and forming an upper isolation layer by removing at least a portion of the upper gate electrode and at least a portion of each of the plurality of upper sheet patterns.

In some but not all embodiments, a width of the upper isolation layer in the second direction may be greater than a width of the plurality of upper sheet patterns in the second direction.

In some but not all embodiments, a width of the upper isolation layer in a third direction intersecting each of the first direction and the second direction may be less than a width of the plurality of upper sheet patterns in the third direction.

In some but not all embodiments, forming the upper isolation layer may include forming a first trench penetrating at least a portion of the upper gate electrode and at least a portion of the plurality of upper sheet patterns; and depositing an insulating material in the first trench such that the upper gate electrode is exposed.

In some but not all embodiments, a lower surface of the upper isolation layer may contact the upper gate electrode and may include a curved surface.

In some but not all embodiments, the semiconductor device manufacturing method may further include forming a lower isolation layer by removing at least a portion of the lower gate electrode and at least a portion of each of the plurality of lower sheet patterns.

In some but not all embodiments, the semiconductor device manufacturing method may further include removing the substrate and the lower pattern prior to forming the lower isolation layer.

In some but not all embodiments, a width of the lower isolation layer in the second direction may be greater than a width of the plurality of lower sheet patterns in the second direction.

In some but not all embodiments, forming the lower isolation layer may include forming a second trench penetrating at least a portion of the lower gate electrode and at least a portion of each of the plurality of lower sheet patterns, and depositing an insulating material in the second trench such that the lower gate electrode is exposed.

In some but not all embodiments, the semiconductor device manufacturing method may further include forming a lower gate contact on the lower gate electrode.

### BRIEF DESCRIPTION OF THE DRAWINGS

The above and other aspects will become more apparent by describing in detail example embodiments thereof with reference to the attached drawings, in which:

FIGS. 1 and 2 are exemplary plan views illustrating a semiconductor device according to some embodiments;

FIG. 3 is a cross-sectional view taken along line A-A of FIGS. 1 and 2;

FIG. 4 is a cross-sectional view taken along line B-B of FIGS. 1 and 2;

FIG. 5 is a cross-sectional view taken along line C-C of FIGS. 1 and 2;

FIG. 6 is an enlarged view of a region Q1 of FIG. 4, according to some embodiments;

FIG. 7 is an enlarged view of a region Q1 of FIG. 4, according to some embodiments;

FIG. 8 is a diagram illustrating a semiconductor device according to some embodiments;

FIGS. 9 and 10 are diagrams illustrating a semiconductor device according to some embodiments;

FIG. 11 is a diagram illustrating a semiconductor device according to some embodiments;

FIG. 12 is a diagram illustrating a semiconductor device according to some embodiments;

FIG. 13 is a diagram illustrating a semiconductor device according to some embodiments;

FIG. 14 is a diagram illustrating a semiconductor device according to some embodiments;

FIGS. 15 through 27 are diagrams illustrating a method of manufacturing a semiconductor device according to some embodiments.

### DETAILED DESCRIPTION

In the present disclosure, the terms “upper”, “lower”, “upper surface”, and “lower surface” are for convenience of description, and are not limiting. Upper, lower, upper surface, and lower surface are described based on what is shown in the drawings. It will be appreciate that when the drawings are flipped vertically, the terms referring to the up-down relationship may change.

As used in this specification, a phrase using the form “at least one of A, B, or C” includes within its scope “only A”, “only B”, “only C”, “A and B”, “A and C”, “B and C” and “A, B, and C.”

According to various embodiments, by forming an upper isolation layer on the upper gate electrode, a number of upper sheet patterns may be adjusted. As a result, the electrical characteristics of a semiconductor device may be easily adjusted, and the reliability of the semiconductor device may be improved.

According to various embodiments, by forming a lower isolation layer on the lower gate electrode, a number of lower sheet patterns may be adjusted. As a result, the electrical characteristics of a semiconductor device may be easily adjusted, and the reliability of the semiconductor device may be improved.

According to various embodiments, by forming the width of a first active area on a first region to be the same as the width of a second active area on a second region, the difficulty of the manufacturing process may be reduced.

Hereinafter, with reference to the drawings, semiconductor devices and methods of manufacturing the semiconductor devices according to some embodiments are described in detail.

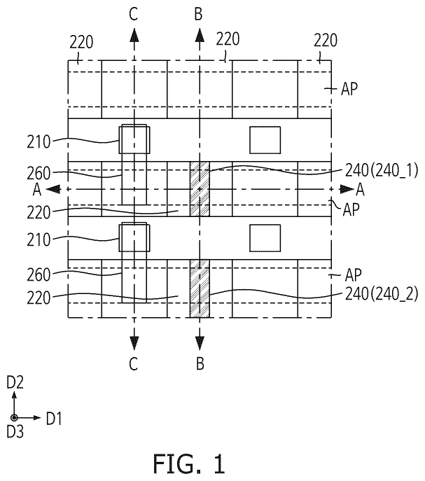

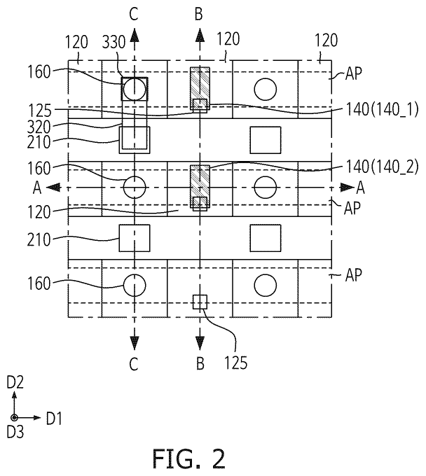

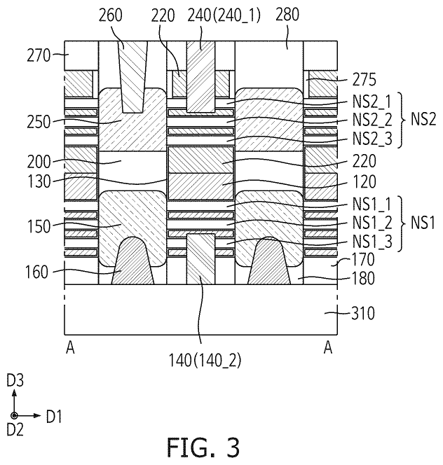

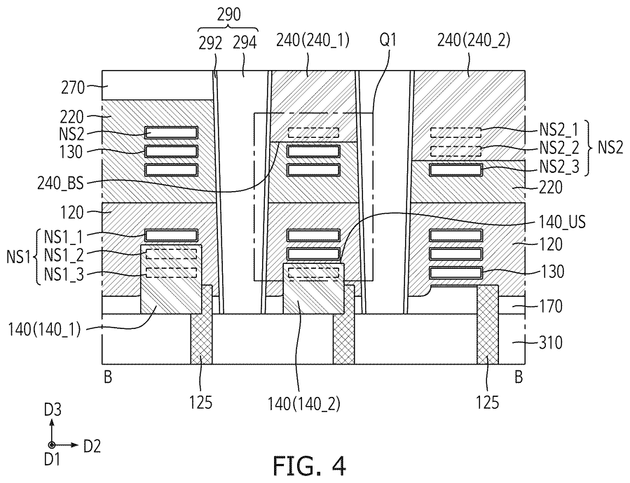

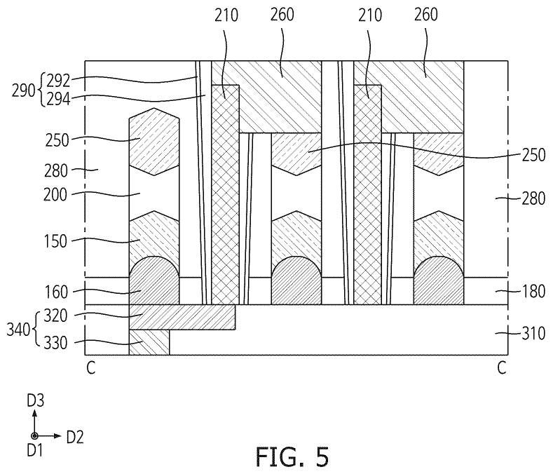

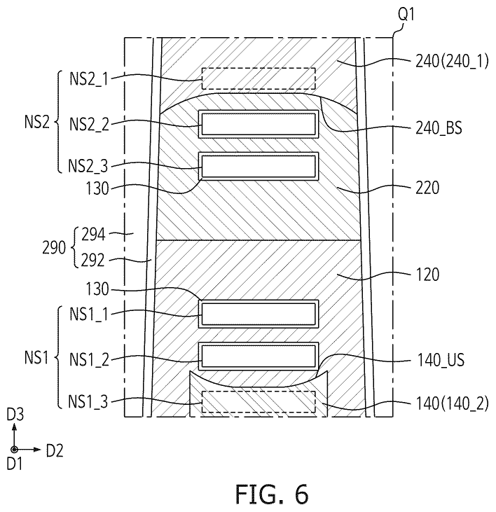

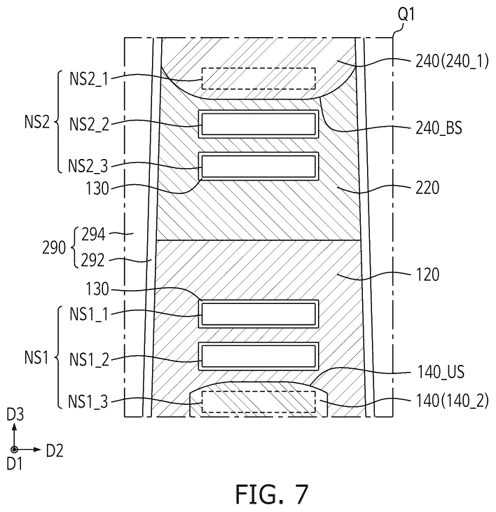

FIGS. 1 and 2 are exemplary plan views illustrating a semiconductor device according to some embodiments. FIG. 3 is a cross-sectional view taken along line A-A of FIGS. 1 and 2. FIG. 4 is a cross-sectional view taken along line B-B of FIGS. 1 and 2. FIG. 5 is a cross-sectional view taken along line C-C of FIGS. 1 and 2. FIG. 6 is an enlarged view of a region Q1 of FIG. 4, according to some embodiments. FIG. 7 is an enlarged view of a region Q1 of FIG. 4, according to some embodiments.

Referring to FIGS. 1 through 7, according to some embodiments, the semiconductor device may include a lower wiring insulating layer 310, a lower wiring structure 340, a plurality of lower sheet patterns NS1, a lower gate electrode 120, a lower gate contact 125, a lower isolation layer 140, a lower source/drain pattern 150, a lower source/drain contact 160, a lower interlayer insulating film 180, a lower capping pattern 170, a plurality of upper sheet patterns NS2, an upper gate electrode 220, an upper isolation layer 240, an upper source/drain pattern 250, an upper source/drain contact 260, a gate capping pattern 270, a gate spacer 275, an upper interlayer insulating film 280, and a gate separation structure 290. It is noted that, for reference, FIG. 1 is drawn mainly around the upper gate electrode 220, the upper isolation layer 240, and the upper source/drain contact 260, and FIG. 2 is drawn mainly around the lower gate electrode 120, the lower isolation layer 140, the lower source/drain contact 160, and the lower gate contact 125.

According to some embodiments, the semiconductor device may include a metal oxide semiconductor field-effect transistor (MOSFET). In some embodiments, the semiconductor device may include a three-dimensional multi-stacked semiconductor device referred to as a gate-all-around (GAA) transistor or multi-bridge channel FET (MBCFET).

The lower wiring insulating layer 310 may include, for example, at least one of silicon oxide, silicon nitride, silicon oxynitride, or a low-k dielectric material. The low-k dielectric material may include, for example, at least one material selected from Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethylcyCloTetraSiloxane (OMCTS), HexaMethylDiSiloxane (HMDS), TriMethylSilyl Borate (TMSB), DiAcetoxyDitertiaryButoxySiloxane (DADBS), TriMethylSilil Phosphate (TMSP), PolyTetraFluoroEthylene (PTFE), Tonen SilaZen (TOSZ), Fluoride Silicate Glass (FSG), polypropylene oxide such as polyimide nanofoams, Carbon Doped silicon Oxide (CDO), Organo Silicate Glass (OSG), SiLK, Amorphous Fluorinated Carbon, silica aerogels, silica xerogels, and mesoporous silica, or combination thereof. However, the present disclosure is not limited thereto.

An active area AP may be disposed on the lower wiring insulating layer 310. The active area AP may be an area where the plurality of lower sheet patterns NS1, the lower source/drain pattern 150, the plurality of upper sheet patterns NS2, and the upper source/drain pattern 250 are disposed. The active area AP may extend in a first direction D1. The first direction D1 may intersect a second direction D2. For example, the first direction D1 may be perpendicular to the second direction D2. A third direction D3 may intersect each of the first direction D1 and the second direction D2. For example, the third direction D3 may be perpendicular to each of the first direction D1 and the second direction D2. The first direction D1 and the second direction D2 may be directions parallel to an upper surface of the lower wiring insulating layer 310, and the third direction D3 may be a direction perpendicular to the upper surface of the lower wiring insulating layer 310.

The plurality of lower sheet patterns NS1 may be disposed on the active area AP. The plurality of lower sheet patterns NS1 may be spaced apart from the lower wiring insulating layer 310 in the third direction D3. Each of the plurality of lower sheet patterns NS1 may have a nanosheet shape. Each of the plurality of lower sheet patterns NS1 may be spaced apart from each another in the third direction D3. Three lower sheet patterns NS1 are shown, according to an embodiment, but the present disclosure is not limited to three lower sheet patterns NS1.

Each lower sheet pattern NS1 may include one among a silicon (Si) elemental semiconductor, silicon germanium (SiGe), a IV-IV compound semiconductor, or a III-V compound semiconductor.

The IV-IV compound semiconductor may be, for example, a binary or ternary compound including at least two among carbon (C), silicon (Si), germanium (Ge), and tin (Sn).

The III-V compound semiconductor may be, for example, a binary compound, ternary compound, or quaternary compound formed by combining at least one III-group element selected from aluminum (Al), gallium (Ga), or indium (In) with at least one V-group element selected from phosphorus (P), arsenic (As), and antimony (Sb).

The plurality of lower sheet patterns NS1 may include a first lower sheet pattern NS1_1, a second lower sheet pattern NS1_2, and a third lower sheet pattern NS1_3. The first lower sheet pattern NS1_1 may be disposed on the second lower sheet pattern NS1_2, and the second lower sheet pattern NS1_2 may be disposed on the third lower sheet pattern NS1_3.

The lower gate electrode 120 may be disposed on the plurality of lower sheet patterns NS1. The lower gate electrode 120 may surround the plurality of lower sheet patterns NS1. The lower gate electrode 120 may surround four faces of each lower sheet pattern NS1. For example, the lower gate electrode 120 may surround an upper surface, a lower surface, and both side surfaces of each lower sheet pattern NS1, as illustrated, for example, in FIGS. 4 and 6. Here, the upper surface and the lower surface of each lower sheet pattern NS1 refer to faces that face each other in the third direction D3, and the two side surfaces of each lower sheet pattern NS1 refer to faces that face each other in the second direction D2.

The lower gate electrode 120 may extend in the second direction D2. The lower gate electrode 120 may intersect the active area AP. The lower gate electrode 120 may be disposed between the third lower sheet pattern NS1_3 and the lower capping pattern 170. The lower gate electrode 120 may be disposed between the third lower sheet pattern NS1_3 and the second lower sheet pattern NS1_2, and between the second lower sheet pattern NS1_2 and the first lower sheet pattern NS1_1. The lower gate electrode 120 may be disposed on the upper surface of the first lower sheet pattern NS1_1.

The lower isolation layer 140 may be disposed on the upper surface of the lower wiring insulating layer 310. The lower isolation layer 140 may be disposed between lower source/drain patterns 150 that are adjacent in the first direction D1. The lower isolation layer 140 may extend in the third direction D3. The lower isolation layer 140 may penetrate the lower capping pattern 170 and a lower surface of the lower gate electrode 120. The lower isolation layer 140 may penetrate a portion of a gate insulating layer 130. The lower isolation layer 140 may penetrate at least a portion of some of the plurality of lower sheet patterns NS1.

A second lower isolation layer 140_2 may penetrate the third lower sheet pattern NS1_3. The second lower isolation layer 140_2 may divide the third lower sheet pattern NS1_3 into a first portion and a second portion (see FIG. 3). The second lower isolation layer 140_2 may be disposed between the first portion and the second portion of the third lower sheet pattern NS1_3. As shown in FIG. 3, the first portion and the second portion of the third lower sheet pattern NS1_3 may be spaced apart in the first direction D1.

In some embodiments, a first lower isolation layer 140_1 may penetrate each of the third lower sheet pattern NS1_3 and the second lower sheet pattern NS1_2. The first lower isolation layer 140_1 may divide each of the third lower sheet pattern NS1_3 and the second lower sheet pattern NS1_2 into a first portion and a second portion (in a similar manner that the second lower isolation layer 140_2 divides the third lower sheet pattern NS1_3 in FIG. 3). The first lower isolation layer 140_1 may be disposed between the first portion and the second portion of the third lower sheet pattern NS1_3, and between the first portion and the second portion of the second lower sheet pattern NS1_2. The first portion and the second portion of the third lower sheet pattern NS1_3 may be spaced apart in the first direction D1, and the first portion and the second portion of the second lower sheet pattern NS1_2 may be spaced apart in the first direction D1 (in a similar manner that the second lower isolation layer 140_2 divides the third lower sheet pattern NS1_3 in FIG. 3).

An upper surface of the lower isolation layer 140 may be disposed on the lower gate electrode 120. In some embodiments, the upper surface of the lower isolation layer 140 may contact the lower gate electrode 120. The upper surface of the lower isolation layer 140 may be disposed within the lower gate electrode 120. For example, the upper surface of the lower isolation layer 140 may be disposed at a vertical level higher than a lower surface of the lower gate electrode 120.

A width of the lower isolation layer 140 in the second direction D2 may be greater than a width of each of the plurality of lower sheet patterns NS1 in the second direction D2. A width of the lower isolation layer 140 in the first direction D1 may be less than a width of each of the plurality of lower sheet patterns NS1 in the first direction D1. The width of the lower isolation layer 140 in the first direction D1 may be less than a width of the lower gate electrode 120 in the first direction D1. However, the present disclosure is not limited thereto. For example, in an embodiment, the width of the lower isolation layer 140 in the first direction D1 may be the same as the width of the lower gate electrode 120 in the first direction D1.

In some embodiments, a portion of the lower gate electrode 120 may overlap with the lower isolation layer 140 in the third direction D3. For example, a portion of the lower gate electrode 120 may be disposed between the lower isolation layer 140 and the upper gate electrode 220.

The lower gate contact 125 may be disposed on the lower gate electrode 120. The lower gate contact 125 may penetrate the lower wiring insulating layer 310 and the lower capping pattern 170. In some embodiments, the lower gate contact 125 may penetrate a lower surface of the lower gate electrode 120. The lower gate contact 125 may be electrically connected to the lower gate electrode 120. The lower gate contact 125 may include a conductive material.

In some embodiments, the lower gate contact 125 may be disposed on the lower isolation layer 140 and on the lower gate electrode 120. For example, a portion of the lower gate contact 125 may overlap with the lower isolation layer 140 in the third direction D3. The lower gate contact 125 may contact each of the lower isolation layer 140 and the lower gate electrode 120. However, the present disclosure is not limited thereto.

The plurality of upper sheet patterns NS2 may be disposed on the active area AP. The plurality of upper sheet patterns NS2 may be spaced apart from the plurality of lower sheet patterns NS1 in the third direction D3. The plurality of upper sheet patterns NS2 may overlap the plurality of lower sheet patterns NS1 in the third direction D3. The plurality of upper sheet patterns NS2 may be disposed on the lower gate electrode 120. The lower gate electrode 120 and the upper gate electrode 220 may be disposed between the plurality of upper sheet patterns NS2 and the plurality of lower sheet patterns NS1.

Each of the plurality of upper sheet patterns NS2 may have a nanosheet shape. Each of the plurality of upper sheet patterns NS2 may be spaced apart from each another in the third direction D3. Three upper sheet patterns NS2 are shown, but the present disclosure is not limited thereto.

A description of the materials of the upper sheet patterns NS2 may be the same as the description of the materials of the lower sheet patterns NS1, and thus a repeated description thereof is omitted for conciseness. In some embodiments, the material of the upper sheet patterns NS2 may be the same as the material of the lower sheet patterns NS1, and thus a repeated description thereof is omitted for conciseness. However, the present disclosure is not limited thereto. For example, the material of the upper sheet patterns NS2 may differ from the material of the lower sheet patterns NS1.

The plurality of upper sheet patterns NS2 may include a first upper sheet pattern NS2_1, a second upper sheet pattern NS2_2, and a third upper sheet pattern NS2_3. The first upper sheet pattern NS2_1 may be disposed on the second upper sheet pattern NS2_2, and the second upper sheet pattern NS2_2 may be disposed on the third upper sheet pattern NS2_3.

The upper gate electrode 220 may be disposed on the lower gate electrode 120. In some embodiments, the upper gate electrode 220 may contact the lower gate electrode 120. For example, a lower surface of the upper gate electrode 220 may contact an upper surface of the lower gate electrode 120. However, the present disclosure is not limited thereto. For example, in some embodiments, the upper gate electrode 220 and the lower gate electrode 120 may be spaced apart in the third direction D3, and an insulating layer may be disposed between the upper gate electrode 220 and the lower gate electrode 120.

The upper gate electrode 220 may surround the plurality of upper sheet patterns NS2. The upper gate electrode 220 may surround four faces of each upper sheet pattern NS2. For example, the upper gate electrode 220 may surround an upper surface, a lower surface, and both side surfaces of each upper sheet pattern NS2. Here, the upper surface and the lower surface of each upper sheet pattern NS2 refer to faces that face each other in the third direction D3, and the two side surfaces of each upper sheet pattern NS2 refer to faces that face each other in the second direction D2.

The upper gate electrode 220 may extend in the second direction D2. The upper gate electrode 220 may intersect the active area AP. The upper gate electrode 220 may be disposed between the third upper sheet pattern NS2_3 and the lower gate electrode 120. The upper gate electrode 220 may be disposed between the third upper sheet pattern NS2_3 and the second upper sheet pattern NS2_2, and between the second upper sheet pattern NS2_2 and the first upper sheet pattern NS2_1. The upper gate electrode 220 may be disposed on an upper surface of the first upper sheet pattern NS2_1.

Each of the lower gate electrode 120 and the upper gate electrode 220 may include at least one of a metal, a metal alloy, a conductive metal nitride, a metal silicide, a doped semiconductor material, a conductive metal oxide, or a conductive metal oxynitride. For example, in some embodiments, each of the lower gate electrode 120 and the upper gate electrode 220 may include at least one selected from titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or a combination thereof, without limitation. The conductive metal oxide and conductive metal oxynitride may include oxidized forms of the above materials, but the present disclosure is not limited thereto.

The upper isolation layer 240 may be disposed between upper source/drain patterns 250 that are adjacent in the first direction D1. The upper isolation layer 240 may extend in the third direction D3. The upper isolation layer 240 may penetrate the gate capping pattern 270 and an upper surface of the upper gate electrode 220. The upper isolation layer 240 may penetrate a portion of the gate insulating layer 130. The upper isolation layer 240 may penetrate at least a portion of some of the plurality of upper sheet patterns NS2.

In some embodiments, a first upper isolation layer 240_1 may penetrate the first upper sheet pattern NS2_1. The first upper isolation layer 240_1 may divide the first upper sheet pattern NS2_1 into a first portion and a second portion, as illustrated in FIG. 3. The first upper isolation layer 240_1 may be disposed between the first portion and the second portion of the first upper sheet pattern NS2_1. The first portion of the first upper sheet pattern NS2_1 may be spaced apart from the second portion in the first direction D1.

A second upper isolation layer 240_2 may penetrate the first upper sheet pattern NS2_1 and the second upper sheet pattern NS2_2. The second upper isolation layer 240_2 may divide each of the first upper sheet pattern NS2_1 and the second upper sheet pattern NS2_2 into a first portion and a second portion (in a similar manner that the first upper isolation layer 240_1 divides the first upper sheet pattern NS2_1 in FIG. 3). The first upper isolation layer 240_1 may be disposed between the first portion and the second portion of each of the first upper sheet pattern NS2_1 and the second upper sheet pattern NS2_2. The first portion of each of the first upper sheet pattern NS2_1 and the second upper sheet pattern NS2_2 may be spaced apart from the second portion in the first direction D1.

A lower surface of the upper isolation layer 240 may be disposed on the upper gate electrode 220. In some embodiments, the lower surface of the upper isolation layer 240 may contact the upper gate electrode 220. The lower surface of the upper isolation layer 240 may be disposed within the upper gate electrode 220. For example, the lower surface of the upper isolation layer 240 may be disposed at a vertical level lower than an upper surface of the upper gate electrode 220.

A width of the upper isolation layer 240 in the second direction D2 may be greater than a width of each of the plurality of upper sheet patterns NS2 in the second direction D2. A width of the upper isolation layer 240 in the first direction D1 may be less than a width of each of the plurality of upper sheet patterns NS2 in the first direction D1. The width of the upper isolation layer 240 in the first direction D1 may be less than a width of the upper gate electrode 220 in the first direction D1. However, the present disclosure is not limited thereto. For example, in some embodiments, the width of the upper isolation layer 240 in the first direction D1 may be the same as the width of the upper gate electrode 220 in the first direction D1.

In some embodiments, a portion of the upper gate electrode 220 may overlap with the upper isolation layer 240 in the third direction D3. For example, a portion of the upper gate electrode 220 may be disposed between the upper isolation layer 240 and the lower gate electrode 120.

In some embodiments, the upper isolation layer 240 and the lower isolation layer 140 may overlap in the third direction D3. For example, the first upper isolation layer 240_1 and the second lower isolation layer 140_2 may overlap in the third direction D3.

Each of the upper isolation layer 240 and the lower isolation layer 140 may include an insulating material. For example, each of the upper isolation layer 240 and the lower isolation layer 140 may include one of silicon nitride (SiN), silicon oxynitride (SiON), silicon oxycarbonitride (SiOCN), or silicon carbonitride (SiCN).

Depending on the design of the semiconductor device, the electrical characteristics of a transistor included in the semiconductor device may vary. According to some embodiments, the semiconductor device may include the lower isolation layer 140 and the upper isolation layer 240, thereby allowing an adjustment of the number of sheet patterns NS1, NS2. For example, there may be two upper sheet patterns NS2 surrounded by the upper gate electrode 220 where the first upper isolation layer 240_1 is disposed, and there may be one lower sheet pattern NS1 surrounded by the lower gate electrode 120 where the first lower isolation layer 140_1 is disposed. By adjusting the number of sheet patterns NS1, NS2 using the lower isolation layer 140 and the upper isolation layer 240, the electrical characteristics of the semiconductor device may be easily adjusted, and reliability of the semiconductor device may be improved.

In some embodiments, an upper surface 140_US of the lower isolation layer 140 may include a curved surface, and a lower surface 240_BS of the upper isolation layer 240 may include a curved surface (see, e.g., FIGS. 6 and 7). The upper surface 140_US of the lower isolation layer 140 may contact the lower gate electrode 120, and the lower surface 240_BS of the upper isolation layer 240 may contact the upper gate electrode 220.

As shown in FIG. 6, the upper surface 140_US of the lower isolation layer 140 may include a concave curved surface, and the lower surface 240_BS of the upper isolation layer 240 may include a concave curved surface. As shown in FIG. 7, the upper surface 140_US of the lower isolation layer 140 may include a convex curved surface, and the lower surface 240_BS of the upper isolation layer 240 may include a convex curved surface. In order to form the lower isolation layer 140 and the upper isolation layer 240, a portion of the sheet patterns NS1, NS2 and the gate electrodes 120, 220 may be removed. In this case, the materials constituting the sheet patterns NS1, NS2 and the gate electrodes 120, 220 may differ, and etch rates may differ. As a result, the upper surface 140_US of the lower isolation layer 140 and the lower surface 240_BS of the upper isolation layer 240 may form curved surfaces as shown in FIGS. 6 and 7.

The gate insulating layer 130 may be disposed between the lower gate electrode 120 and the plurality of lower sheet patterns NS1, and between the upper gate electrode 220 and the plurality of upper sheet patterns NS2. The gate insulating layer 130 may be disposed between the lower gate electrode 120 and the lower source/drain pattern 150, and between the upper gate electrode 220 and the upper source/drain pattern 250.

In some embodiments, the gate insulating layer 130 may include multiple layers. For example, the gate insulating layer 130 may include an interfacial insulating layer and a high-k insulating layer. The interfacial insulating layer may include, for example, silicon oxide. The high-k insulating layer may include a high dielectric constant material having a dielectric constant greater than that of the interfacial insulating layer. For example, in some embodiments, the high-k insulating layer may include at least one selected from boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, without limitation.

The gate spacer 275 may be disposed on a side surface of the upper gate electrode 220. For example, the gate spacer 275 may be disposed on both side surfaces of the upper gate electrode 220 that is located on the first upper sheet pattern NS2_1. The gate spacer 275 may extend along the side surface of the upper gate electrode 220. The gate spacer 275 may not be disposed between upper sheet patterns NS2 that are adjacent in the third direction D3.

In some embodiments, the gate spacer 275 may include, for example, at least one selected from silicon nitride (SiN), silicon oxynitride (SiON), silicon oxide (SiO2), silicon oxycarbonitride (SiOCN), silicon boron nitride (SiBN), silicon oxyboron nitride (SiOBN), silicon oxycarbide (SiOC), and combinations thereof. Although the gate spacer 275 is shown as a single layer, that is merely for convenience of description, and the present disclosure is not limited thereto.

The gate capping pattern 270 may be disposed on the upper surface of the upper gate electrode 220 and on the upper surface of the gate spacer 275. The gate capping pattern 270 may cover the upper surface of the upper gate electrode 220. Although the gate capping pattern 270 is shown in contact with the upper surface of the gate spacer 275, the present disclosure is not limited thereto. For example, in some embodiments, the gate capping pattern 270 may be disposed between a pair of gate spacers 275 and may contact side surfaces of the gate spacers 275.

For example, in some embodiments, the gate capping pattern 270 may include, for example, at least one selected from silicon nitride (SiN), silicon oxynitride (SiON), silicon carbonitride (SiCN), or silicon oxycarbonitride (SiOCN). The gate capping pattern 270 may include a material having an etch selectivity relative to the upper interlayer insulating film 280.

The upper interlayer insulating film 280 may be disposed on the upper source/drain pattern 250. The upper interlayer insulating film 280 may cover the upper surface of the upper source/drain pattern 250. Although not shown, in some embodiments, an etch stop film may be disposed between the upper interlayer insulating film 280 and the upper surface of the upper source/drain pattern 250.

The upper interlayer insulating film 280 may include, for example, at least one of silicon oxide (SiO), silicon nitride (SiN), silicon oxynitride (SiON), or a low-k dielectric material. In some embodiments, the low-k dielectric material may include, for example, at least one selected from Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethyleyCloTetraSiloxane (OMCTS), HexaMethylDiSiloxane (HMDS), TriMethylSilyl Borate (TMSB), DiAcetoxyDitertiaryButoSiloxane (DADBS), TriMethylSilil Phosphate (TMSP), PolyTetraFluoroEthylene (PTFE), Tonen SilaZen (TOSZ), Fluoride Silicate Glass (FSG), polypropylene oxide such as polyimide nanofoams, Carbon Doped silicon Oxide (CDO), Organo Silicate Glass (OSG), SiLK, Amorphous Fluorinated Carbon, silica aerogels, silica xerogels, and mesoporous silica, without limitation.

The gate separation structure 290 may be disposed on the lower insulating layer 310. The gate separation structure 290 may extend in the first direction D1 and the third direction D3. The gate separation structure 290 may penetrate each of the upper gate electrode 220 and the lower gate electrode 120. The gate separation structure 290 may separate each of the upper gate electrode 220 and the lower gate electrode 120. A side surface of the gate separation structure 290 may contact each of the upper gate electrode 220 and the lower gate electrode 120.

The lower isolation layer 140 and the upper isolation layer 240 may be disposed on one side of the gate separation structure 290. In some embodiments, the lower isolation layer 140 and the upper isolation layer 240 may be disposed between gate separation structures 290. For example, the first upper isolation layer 240_1 and the second lower isolation layer 140_2 may be disposed between gate separation structures 290.

In some embodiments, a width of the upper isolation layer 240 in the second direction D2 may be equal to a distance between the gate separation structure 290 and another gate separation structure 290 adjacent in the second direction D2. For example, the width in the second direction D2 of the first upper isolation layer 240_1 may be equal to the distance in the second direction D2 between gate separation structures 290. In some embodiments, the upper isolation layer 240 may not have the upper gate electrode 220 disposed between the upper isolation layer 240 and the gate separation structure 290.

The gate separation structure 290 may include a liner film 292 and a filling insulating film 294. The liner film 292 may define a side surface of the gate separation structure 290. The filling insulating film 294 may be disposed within the liner film 292. For example, the liner film 292 may include one of silicon nitride (SiN), silicon oxynitride (SiON), silicon oxycarbonitride (SiOCN), silicon boron nitride (SiBN), silicon oxyboron nitride (SiOBN), or silicon carbonitride (SiCN). In some embodiments, the filling insulating film 294 may include, for example, at least one selected from silicon oxide (SiO2), silicon oxynitride (SiON), silicon oxycarbonitride (SiOCN), silicon oxyboron nitride (SiOBN), silicon oxycarbide (SiOC), and combinations thereof.

The lower source/drain pattern 150 may be disposed on the active area AP. The lower source/drain pattern 150 may be disposed on the lower interlayer insulating film 180. The lower source/drain pattern 150 may be disposed on side surfaces of the plurality of lower sheet patterns NS1. The lower source/drain pattern 150 may be connected to the plurality of lower sheet patterns NS1. A portion of the side surface of the lower source/drain pattern 150 may contact the lower sheet patterns NS1. Another portion of the side surface of the lower source/drain pattern 150 may contact the gate insulating layer 130. The lower source/drain pattern 150 may be disposed on at least one side of the lower gate electrode 120.

The lower source/drain pattern 150 may be an epitaxial pattern formed by a selective epitaxial growth process using the plurality of lower sheet patterns NS1 as seeds. The lower source/drain pattern 150 may serve as the source/drain of a transistor that uses the plurality of lower sheet patterns NS1 as channel regions.

A middle interlayer insulating film 200 may be disposed on the lower source/drain pattern 150. The middle interlayer insulating film 200 may be disposed between the lower source/drain pattern 150 and the upper source/drain pattern 250. The middle interlayer insulating film 200 may include an insulating material. A description of the material of the middle interlayer insulating film 200 may be the same as the description of the material of the upper interlayer insulating film 280.

The upper source/drain pattern 250 may be disposed on the active area AP. The upper source/drain pattern 250 may be disposed on the middle interlayer insulating film 200. The upper source/drain pattern 250 may be disposed on side surfaces of the plurality of upper sheet patterns NS2. The upper source/drain pattern 250 may be connected to the plurality of upper sheet patterns NS2. A portion of the side surface of the upper source/drain pattern 250 may contact the upper sheet patterns NS2. Another portion of the side surface of the upper source/drain pattern 250 may contact the gate insulating layer 130. The upper source/drain pattern 250 may be disposed on at least one side of the upper gate electrode 220. The upper source/drain pattern 250 may overlap the lower source/drain pattern 150 in the third direction D3.

The upper source/drain pattern 250 may be an epitaxial pattern formed by a selective epitaxial growth process using the plurality of upper sheet patterns NS2 as seeds. The upper source/drain pattern 250 may serve as the source/drain of a transistor that uses the plurality of upper sheet patterns NS2 as channel regions.

Each of the lower source/drain pattern 150 and the upper source/drain pattern 250 may include a semiconductor material. For example, each of the lower source/drain pattern 150 and the upper source/drain pattern 250 may include silicon (Si) or germanium (Ge) as an elemental semiconductor material. In addition, each of the lower source/drain pattern 150 and the upper source/drain pattern 250 may include a binary or ternary compound comprising at least two among carbon (C), silicon (Si), germanium (Ge), or tin (Sn), or a compound doped with a Group IV element. For example, each of the lower source/drain pattern 150 and the upper source/drain pattern 250 may include silicon (Si), silicon-germanium (SiGe), germanium (Ge), silicon carbide (SiC), or the like, but the present disclosure is not limited thereto.

Each of the lower source/drain pattern 150 and the upper source/drain pattern 250 may include a dopant doped into the semiconductor material. The dopant may include at least one of boron (B), phosphorus (P), carbon (C), arsenic (As), antimony (Sb), bismuth (Bi), or oxygen (O), but embodiments are not limited thereto. In some embodiments, the lower source/drain pattern 150 and the upper source/drain pattern 250 may include dopants of different conductivity types.

Each of the lower source/drain pattern 150 and the upper source/drain pattern 250 is shown as a single layer, but a single layer is merely for convenience of description and embodiments are not limited thereto. In an embodiment, each of the lower source/drain pattern 150 and the upper source/drain pattern 250 may include multiple layers containing different materials. In some embodiments, each of the lower source/drain pattern 150 and the upper source/drain pattern 250 may include the same material, but multiple layers with different concentrations of the constituent material.

The upper source/drain contact 260 may be disposed on the upper source/drain pattern 250. The upper source/drain contact 260 may penetrate the upper interlayer insulating film 280 and the upper surface of the upper source/drain pattern 250. One end of the upper source/drain contact 260 may be disposed in the upper source/drain pattern 250. For example, a lower surface of the upper source/drain contact 260 may be disposed in the upper source/drain pattern 250. The upper source/drain contact 260 may be electrically connected to the upper source/drain pattern 250.

The lower source/drain contact 160 may be disposed on the lower source/drain pattern 150. The lower source/drain contact 160 may penetrate the lower interlayer insulating film 180 and a lower surface of the lower source/drain pattern 150. One end of the lower source/drain contact 160 may be disposed in the lower source/drain pattern 150. For example, an upper surface of the lower source/drain contact 160 may be disposed in the lower source/drain pattern 150. The lower source/drain contact 160 may be electrically connected to the lower source/drain pattern 150.

Each of the upper source/drain contact 260 and the lower source/drain contact 160 may include a conductive material. Although each of the upper source/drain contact 260 and the lower source/drain contact 160 is shown as a single layer, the present disclosure is not limited thereto. For example, each of the upper source/drain contact 260 and the lower source/drain contact 160 may include a barrier film and a conductive filling film disposed within the barrier film.

A through via 210 may be disposed in the gate separation structure 290. For example, the through via 210 may be disposed in the filling insulating film 294 of the gate separation structure 290. The through via 210 may extend in the third direction D3. One end of the through via 210 may be electrically connected to the lower wiring structure 340, and the other end of the through via 210 may be electrically connected to the upper source/drain contact 260.

In some embodiments, the lower source/drain pattern 150 may be electrically connected to the upper source/drain pattern 250 that is spaced apart in the second direction D2 and the third direction D3. For example, the lower source/drain pattern 150 may be electrically connected to the upper source/drain pattern 250 through the lower source/drain contact 160, the lower wiring structure 340, the through via 210, and the upper source/drain contact 260.

The lower wiring structure 340 may be disposed in the lower wiring insulating layer 310. The lower wiring structure 340 may include a line wiring 320 and a lower via 330. The line wiring 320 may extend in the second direction D2. The line wiring 320 may electrically connect the lower source/drain contact 160 and the through via 210. The lower via 330 may be disposed below the line wiring 320. The lower via 330 may be electrically connected to the line wiring 320.

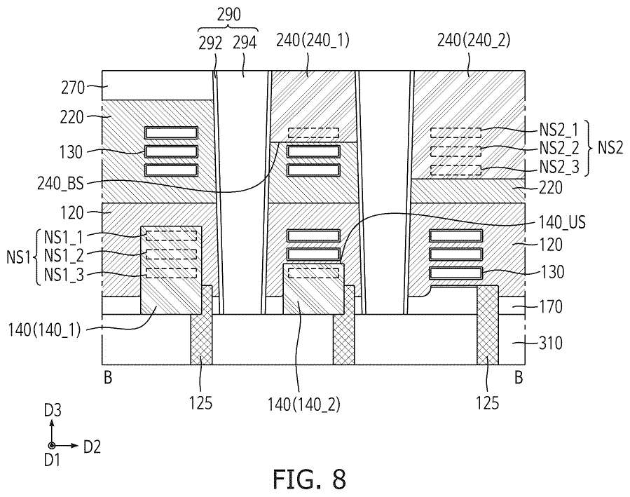

FIG. 8 is a diagram illustrating a semiconductor device according to some embodiments. For convenience of description, emphasis is placed on configurations different from those described with reference to FIGS. 1 through 7 and repeated descriptions to those with respect to FIGS. 1-7 are omitted for conciseness.

Referring to FIG. 8, in a semiconductor device according to some embodiments, a first lower isolation layer 140_1 may penetrate all of the plurality of lower sheet patterns NS1. For example, the first lower isolation layer 140_1 may extend in the third direction D3 and may penetrate each of the first lower sheet pattern NS1_1, the second lower sheet pattern NS1_2, and the third lower sheet pattern NS1_3. Each of the first lower sheet pattern NS1_1, the second lower sheet pattern NS1_2, and the third lower sheet pattern NS1_3 may be separated by the first lower isolation layer 140_1.

In some embodiments, the lower gate electrode 120 may be disposed between an upper surface of the first lower isolation layer 140_1 and the upper gate electrode 220. The upper surface of the first lower isolation layer 140_1 may contact the lower gate electrode 120. However, the present disclosure is not limited thereto. For example, in some embodiments, the first lower isolation layer 140_1 may extend to a lower surface of the upper gate electrode 220 and may contact the upper gate electrode 220.

The second upper isolation layer 240_2 may penetrate all of the plurality of upper sheet patterns NS2. For example, the second upper isolation layer 240_2 may extend in the third direction D3 and may penetrate each of the first upper sheet pattern NS2_1, the second upper sheet pattern NS2_2, and the third upper sheet pattern NS2_3. Each of the first upper sheet pattern NS2_1, the second upper sheet pattern NS2_2, and the third upper sheet pattern NS2_3 may be separated by the second upper isolation layer 240_2.

In some embodiments, the upper gate electrode 220 may be disposed between a lower surface of the second upper isolation layer 240_2 and the lower gate electrode 120. The lower surface of the second upper isolation layer 240_2 may contact the upper gate electrode 220. However, the present disclosure is not limited thereto. For example, in some embodiments, the second upper isolation layer 240_2 may extend to an upper surface of the lower gate electrode 120 and may contact the lower gate electrode 120.

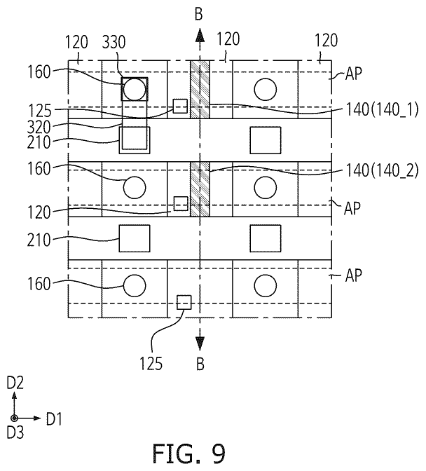

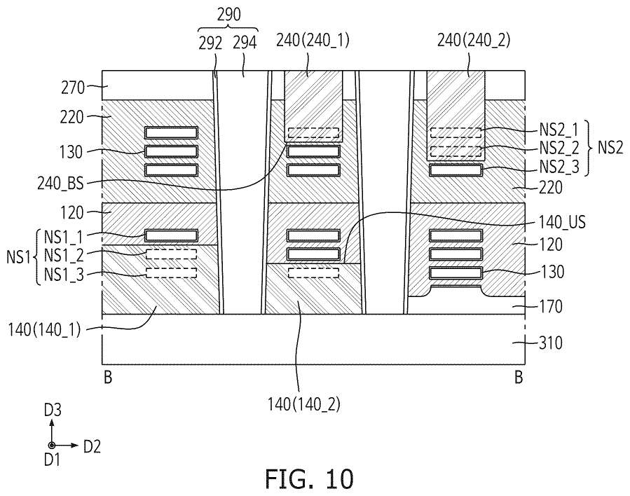

FIGS. 9 and 10 are diagrams illustrating a semiconductor device according to some embodiments. For reference, FIG. 9 is a plan view of a semiconductor device according to some embodiments, and FIG. 10 is a cross-sectional view taken along line B-B of FIG. 9. For convenience of description, emphasis is placed on configurations different from those described with reference to FIGS. 1 through 7 and repeated descriptions to those with respect to FIGS. 1-7 are omitted for conciseness.

Referring to FIGS. 9 and 10, in a semiconductor device according to some embodiments, a width of the lower isolation layer 140 in the second direction D2 may be greater than a width of the lower sheet pattern NS1 in the second direction D2.

In some embodiments, the lower isolation layer 140 may be disposed between gate separation structures 290 that are adjacent in the second direction D2. A width of the lower isolation layer 140 in the second direction D2 may be equal to the distance in the second direction D2 between the gate separation structures 290 adjacent in the second direction D2. For example, the width of the second lower isolation layer 140_2 in the second direction D2 may be equal to the distance in the second direction D2 between gate separation structures 290. The lower gate electrode 120 may not be disposed between the lower isolation layer 140 and the gate separation structure 290.

In some embodiments, the lower gate contact 125 may be disposed on the lower gate electrode 120 and may be spaced apart from the lower isolation layer 140 in the first direction D1. The lower gate contact 125 may be connected to the lower gate electrode 120. In some embodiments, although not shown, a portion of the lower gate contact 125 may be omitted and an upper gate contact may be disposed on the upper gate electrode 220.

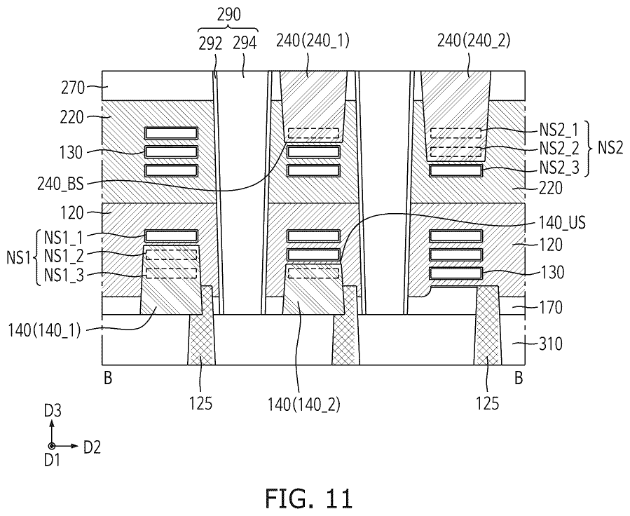

FIG. 11 is a diagram illustrating a semiconductor device according to some embodiments. For convenience of description, emphasis is placed on configurations different from those described with reference to FIGS. 1 through 7 and repeated descriptions to those with respect to FIGS. 1-7 are omitted for conciseness.

Referring to FIG. 11, in a semiconductor device according to some embodiments, widths of each of the lower isolation layer 140, the upper isolation layer 240, and the lower gate contact 125 in the second direction D2 may be non-uniform.

A width of the lower isolation layer 140 in the second direction D2 may decrease as a distance from a lower surface of the lower isolation layer 140 increases. The lower isolation layer 140 may include an inclined side surface. From a cross-sectional perspective, the lower isolation layer 140 may include a tapered shape.

A width of the upper isolation layer 240 in the second direction D2 may decrease as a distance from an upper surface of the upper isolation layer 240 increases. The upper isolation layer 240 may include an inclined side surface. From a cross-sectional perspective, the upper isolation layer 240 may include a tapered shape.

A width of the lower gate contact 125 in the second direction D2 may decrease as a distance from a lower surface of the lower gate contact 125 increases. The lower gate contact 125 may include an inclined side surface. From a cross-sectional perspective, the lower gate contact 125 may include a tapered shape.

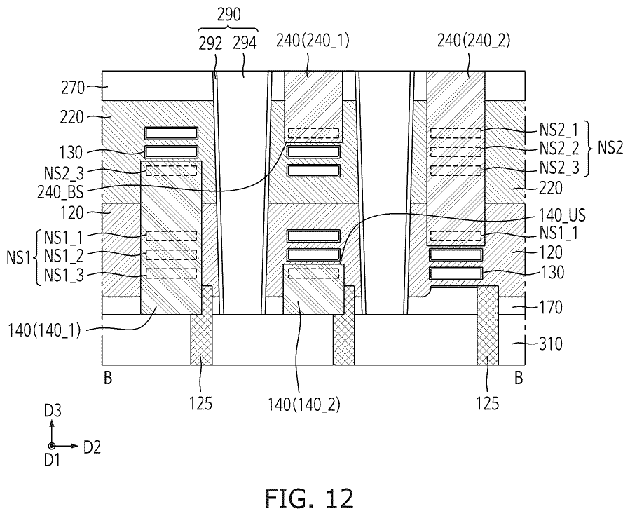

FIG. 12 is a diagram illustrating a semiconductor device according to some embodiments. For convenience of description, emphasis is placed on configurations different from those described with reference to FIGS. 1 through 7 and repeated descriptions to those with respect to FIGS. 1-7 are omitted for conciseness.

Referring to FIG. 12, in a semiconductor device according to some embodiments, the lower isolation layer 140 may penetrate all of the plurality of lower sheet patterns NS1 and a portion of the plurality of upper sheet patterns NS2. For example, the first lower isolation layer 140_1 may extend in the third direction D3 and may penetrate the first lower sheet pattern NS1_1, the second lower sheet pattern NS1_2, the third lower sheet pattern NS1_3, and the third upper sheet pattern NS2_3. One end of the first lower isolation layer 140_1 may be disposed in the upper gate electrode 220. The upper surface of the first lower isolation layer 140_1 may contact the upper gate electrode 220.

The upper isolation layer 240 may penetrate all of the plurality of upper sheet patterns NS2 and a portion of the plurality of upper sheet patterns NS2. For example, the second upper isolation layer 240_2 may extend in the third direction D3 and may penetrate the first upper sheet pattern NS2_1, the second upper sheet pattern NS2_2, the third upper sheet pattern NS2_3, and the first lower sheet pattern NS1_1. One end of the second upper isolation layer 240_2 may be disposed in the lower gate electrode 120. The lower surface of the second upper isolation layer 240_2 may contact the lower gate electrode 120.

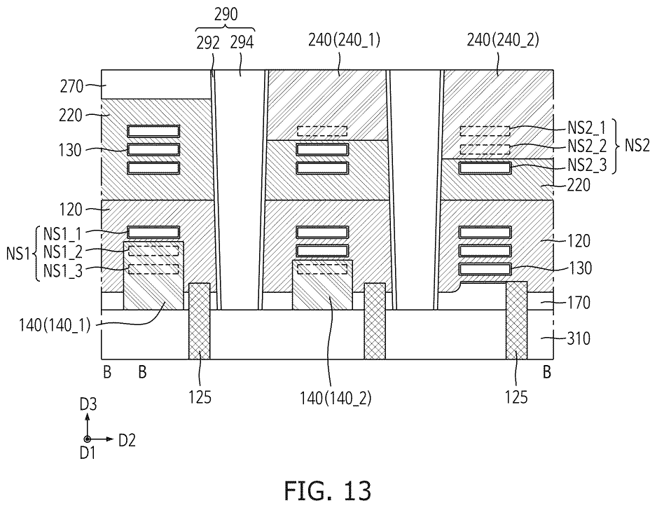

FIG. 13 is a diagram illustrating a semiconductor device according to some embodiments. For convenience of description, emphasis is placed on configurations different from those described with reference to FIGS. 1 through 7 and repeated descriptions to those with respect to FIGS. 1-7 are omitted for conciseness.

Referring to FIG. 13, in a semiconductor device according to some embodiments, the lower gate contact 125 may be disposed on the lower gate electrode 120. The lower gate contact 125 may penetrate the lower wiring insulating layer 310, the lower capping pattern 170, and a lower surface of the lower gate electrode 120. The lower gate contact 125 may be spaced apart from the lower isolation layer 140 in the second direction D2. The lower capping pattern 170 may be disposed between the lower gate contact 125 and the lower isolation layer 140. The lower gate contact 125 may not overlap the lower isolation layer 140 in the third direction D3.

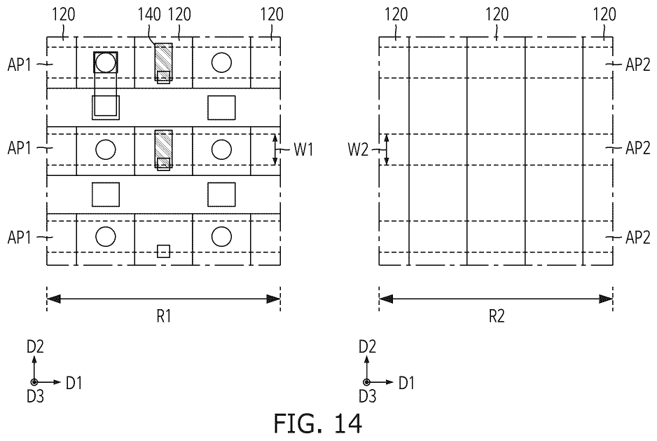

FIG. 14 is a diagram illustrating a semiconductor device according to some embodiments. For convenience of description, emphasis is placed on configurations different from those described with reference to FIGS. 1 through 7 and repeated descriptions to those with respect to FIGS. 1-7 are omitted for conciseness.

Referring to FIG. 14, in a semiconductor device according to some embodiments, the semiconductor device may include a first region R1 and a second region R2.

The first region R1 may be, for example, a region in which the semiconductor device described with reference to FIGS. 1 through 13 is disposed. The second region R2 may have a different semiconductor device than the semiconductor device disposed in the first region R1. For example, a Static Random Access Memory (SRAM) device may be disposed on the first region R1, and devices such as a capacitor, a resistor, an inductor, or a diode may be disposed on the second region R2.

A first active area AP1 extending in the first direction D1 may be disposed on the first region R1. A second active area AP2 extending in the first direction D1 may be disposed on the second region R2. A first width W1 of the first active area AP1 may be the same as a second width W2 of the second active area AP2. Sheet patterns disposed on the first active area AP1 may have the first width W1, and sheet patterns disposed on the second active area AP2 may have the second width W2. The term “width” may refer to a width in the second direction D2.

Depending on a configuration of a semiconductor device, different electrical characteristics may be achieved for each device. In a semiconductor device according to some embodiments, the first width W1 of the first active area AP1 in the first region R1 may be the same as the second width W2 of the second active area AP2 in the second region R2. Accordingly, a process of forming the first active area AP1 and the second active area AP2 may be performed simultaneously. As a result, the difficulty of the semiconductor device manufacturing process may be reduced, and reliability of the semiconductor device may be improved.

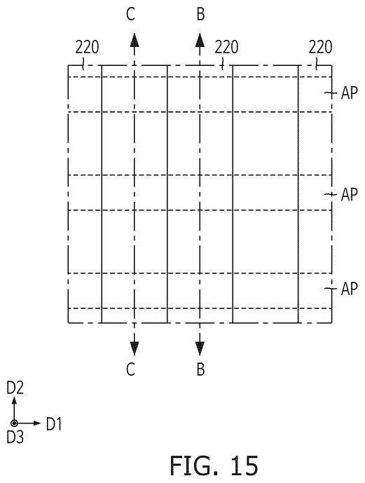

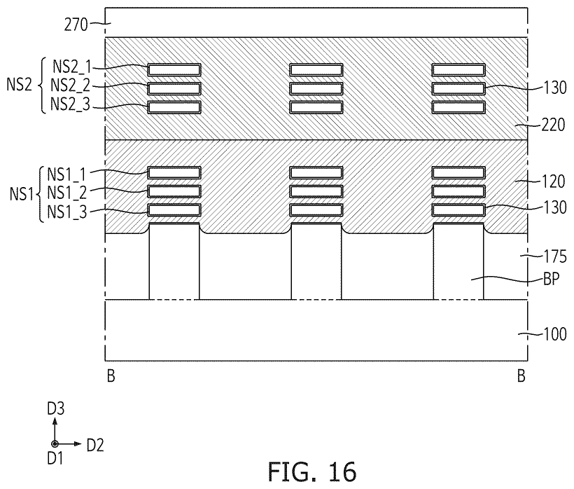

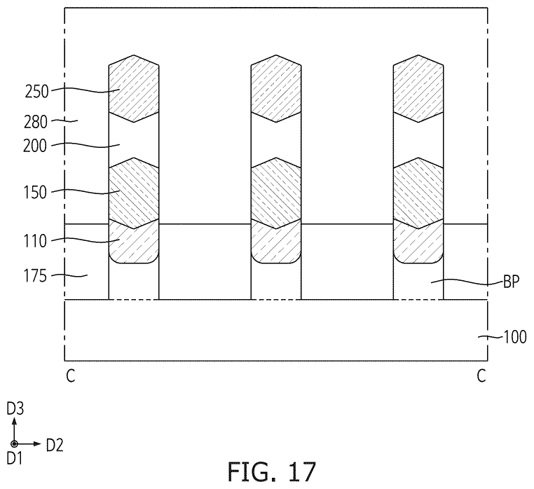

FIGS. 15 through 27 are diagrams illustrating a method of manufacturing a semiconductor device according to some embodiments. For reference, FIG. 15 is a plan view illustrating a method of manufacturing a semiconductor device according to some embodiments. FIGS. 16, 18, 20, 22, 24, and 26 are cross-sectional views taken along line B-B of FIG. 15. FIGS. 17, 19, 21, 23, 25, and 27 are cross-sectional views taken along line C-C of FIG. 15.

Referring to FIGS. 15 through 17, a lower pattern BP, the plurality of lower sheet patterns NS1, the plurality of upper sheet patterns NS2, the lower gate electrode 120, the upper gate electrode 220, a sacrificial pattern 110, the lower source/drain pattern 150, a middle interlayer insulating film 200, the upper source/drain pattern 250, the gate capping pattern 270, and the upper interlayer insulating film 280 may be formed on a substrate 100.

The substrate 100 may be a bulk silicon substrate or a silicon-on-insulator (SOI). In some embodiments, the substrate 100 may include silicon germanium (SiGe), silicon germanium on insulator (SGOI), indium antimonide, lead telluride compounds, indium arsenide, indium phosphide, gallium arsenide, or gallium antimonide, without limitation.

In some embodiments, the lower pattern BP may include the same material as the substrate 100, and a boundary between the lower pattern BP and the substrate 100 may not be distinguished. However, the present disclosure is not limited thereto.

The plurality of lower sheet patterns NS1 may be disposed on the lower pattern BP. The plurality of lower sheet patterns NS1 may be spaced apart from the lower pattern BP in the third direction D3. An element isolation layer 175 may be disposed between the lower pattern BP and another lower pattern BP adjacent in the second direction D2.

The sacrificial pattern 110 may be disposed on the lower pattern BP. The lower source/drain pattern 150 may be disposed on the sacrificial pattern 110. The sacrificial pattern 110 may be disposed between the lower source/drain pattern 150 and the lower pattern BP. The sacrificial pattern 110 may include, for example, a semiconductor material.

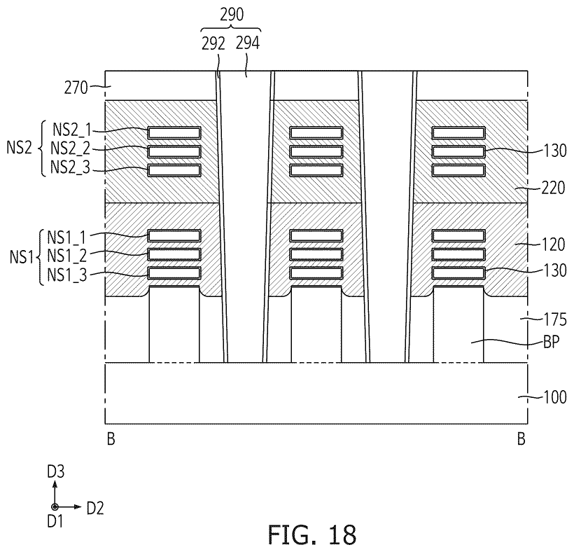

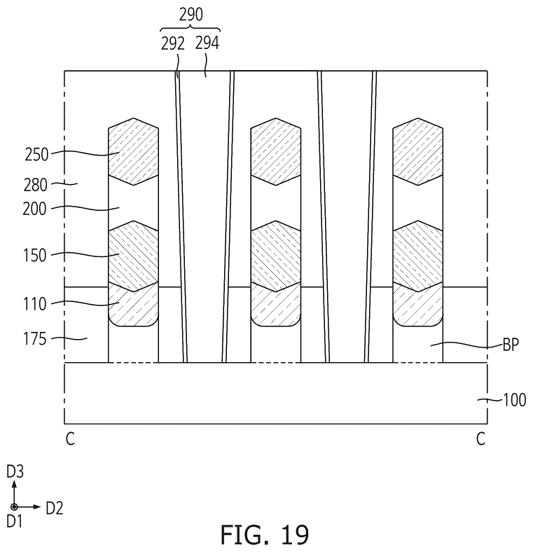

Referring to FIGS. 18 and 19, the gate separation structure 290 may be formed on an upper surface of the substrate 100. The gate separation structure 290 may extend in the first direction D1 and the third direction D3. The gate separation structure 290 may separate each of the lower gate electrode 120 and the upper gate electrode 220. The gate separation structure 290 may include a liner film 292 and a filling insulating film 294.

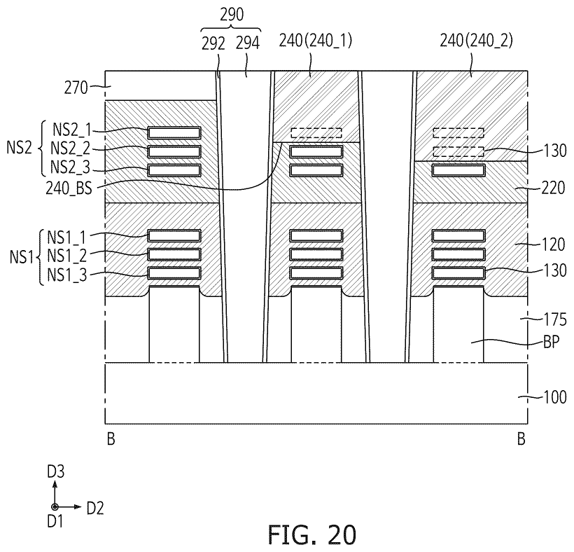

Referring to FIG. 20, the upper isolation layer 240 may be formed on the upper gate electrode 220. A width of the upper isolation layer 240 in the second direction D2 may be greater than a width of the plurality of upper sheet patterns NS2 in the second direction D2.

Specifically, the first upper isolation layer 240_1 and the second upper isolation layer 240_2 may be formed. The first upper isolation layer 240_1 and the second upper isolation layer 240_2 may be formed by different processes.

The first upper isolation layer 240_1 may be formed on the upper gate electrode 220. For example, via a first etching process, a portion of the gate capping pattern 270, a portion of the upper gate electrode 220, and the first upper sheet pattern NS2_1 may be removed, forming a first trench. The first trench may expose the upper gate electrode 220. By depositing an insulating material in the first trench, the first upper isolation layer 240_1 may be formed.

The second upper isolation layer 240_2 may be formed on the upper gate electrode 220. For example, via a second etching process, a portion of the gate capping pattern 270, a portion of the upper gate electrode 220, the first upper sheet pattern NS2_1, and the second upper sheet pattern NS2_2 may be removed, forming a second trench. The second trench may expose the upper gate electrode 220. By depositing an insulating material in the second trench, the second upper isolation layer 240_2 may be formed.

In some embodiments, a width of the upper isolation layer 240 in the second direction D2 may be the same as a distance in the second direction D2 between the gate separation structures 290. For example, the first upper isolation layer 240_1 may be disposed between the gate separation structures 290, and the upper gate electrode 220 may not be disposed between the first upper isolation layer 240_1 and the gate separation structures 290.

In some embodiments, the width of the upper isolation layer 240 in the second direction D2 may be small, as shown in FIG. 10. The width of the upper isolation layer 240 in the second direction D2 may be less than the distance between the gate separation structures 290 in the second direction D2. For example, the upper gate electrode 220 may be disposed between the first upper isolation layer 240_1 and the gate separation structure 290.

A lower surface 240_BS of the upper isolation layer 240 may contact the upper gate electrode 220. Although the lower surface of the upper isolation layer 240 is shown to be flat, the present disclosure is not limited thereto. For example, as in FIGS. 6 and 7, the lower surface 240_BS of the upper isolation layer 240 may include a curved surface.

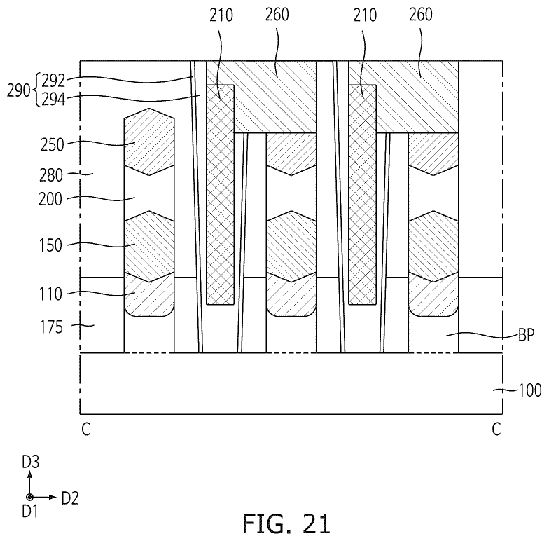

Referring to FIG. 21, a through via 210 and the upper source/drain contact 260 may be formed.

Specifically, the through via 210 may be formed in the filling insulating film 294 of the gate separation structure 290. The through via 210 may extend in the third direction D3. Subsequently, the upper source/drain contact 260 may be formed on the through via 210 and on the upper source/drain pattern 250. The upper source/drain contact 260 may connect the through via 210 and the upper source/drain pattern 250.

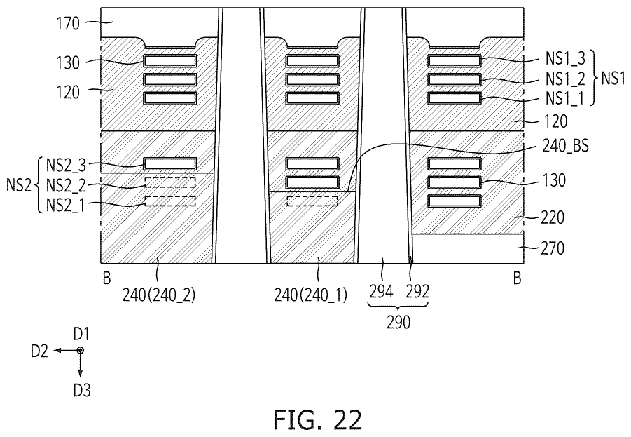

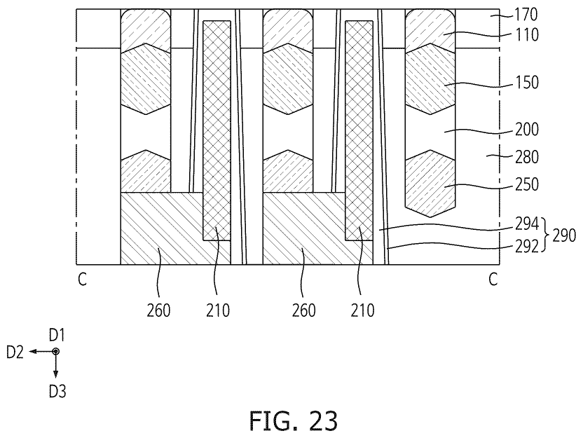

Referring to FIGS. 22 and 23, the lower capping pattern 170 may be formed on the lower gate electrode 120.

In some embodiments, before forming the lower capping pattern 170, the semiconductor device may be flipped. For example, the semiconductor device shown in FIGS. 20 and 21 may be rotated 180 degrees so that the substrate 100 is placed on top. The substrate 100 may then be removed, exposing the lower pattern BP. The substrate 100 may be removed, for example, by a Chemical Mechanical Polishing (CMP) process. Next, the lower pattern BP may be removed, and an insulating material may be deposited to form the lower capping pattern 170. In some embodiments, a portion of the lower capping pattern 170 may be removed to expose the sacrificial pattern 110.

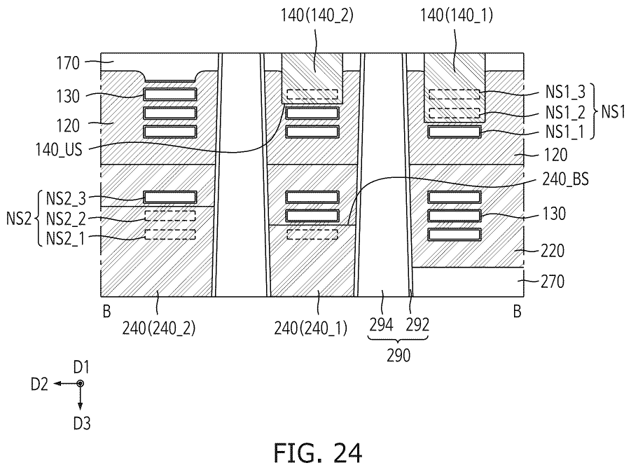

Referring to FIG. 24, the lower isolation layer 140 may be formed on the lower gate electrode 120. A width of the lower isolation layer 140 in the second direction D2 may be greater than a width of the lower sheet patterns NS1 in the second direction D2.

Specifically, a first lower isolation layer 140_1 and a second lower isolation layer 140_2 may be formed. The first lower isolation layer 140_1 and the second lower isolation layer 140_2 may be formed by different processes.

The first lower isolation layer 140_1 may be formed on the lower gate electrode 120. For example, via a third etching process, a portion of the lower capping pattern 170, a portion of the lower gate electrode 120, the second lower sheet pattern NS1_2, and the third lower sheet pattern NS1_3 may be removed, forming a third trench. The third trench may expose the lower gate electrode 120. By depositing an insulating material in the third trench, the first lower isolation layer 140_1 may be formed.

The second lower isolation layer 140_2 may be formed on the lower gate electrode 120. For example, via a fourth etching process, a portion of the lower capping pattern 170, a portion of the lower gate electrode 120, and the third lower sheet pattern NS1_3 may be removed, forming a fourth trench. The fourth trench may expose the lower gate electrode 120. By depositing an insulating material in the fourth trench, the second lower isolation layer 140_2 may be formed.

In some embodiments, the lower gate electrode 120 may be disposed between the lower isolation layer 140 and the gate separation structure 290. However, the present disclosure is not limited thereto. For example, as shown in FIG. 8, the width of the lower isolation layer 140 in the second direction D2 may be formed to be large, and the lower gate electrode 120 may not be disposed between the lower isolation layer 140 and the gate separation structure 290.

In some embodiments, an upper surface 140_US of the lower isolation layer 140 may contact the lower gate electrode 120. Although the upper surface 140_US of the lower isolation layer 140 is shown to be flat, the present disclosure is not limited thereto. For example, as in FIGS. 6 and 7, the upper surface 140_US of the lower isolation layer 140 may include a curved surface.

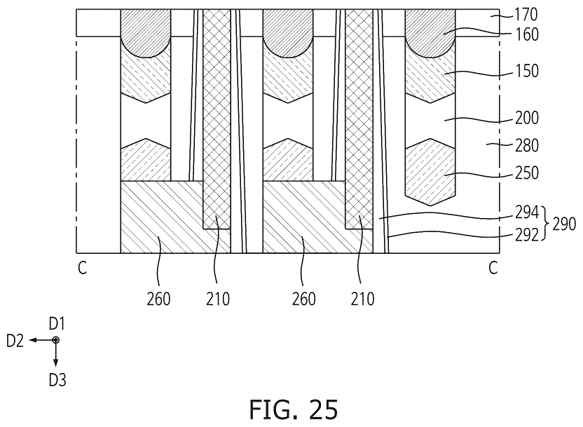

Referring to FIG. 25, the lower source/drain contact 160 may be formed on the lower source/drain pattern 150.

Specifically, a portion of the sacrificial pattern 110 and a portion of the lower source/drain pattern 150 may be removed, and the lower source/drain contact 160 may be formed. One end of the lower source/drain contact 160 may be disposed in the lower source/drain pattern 150.

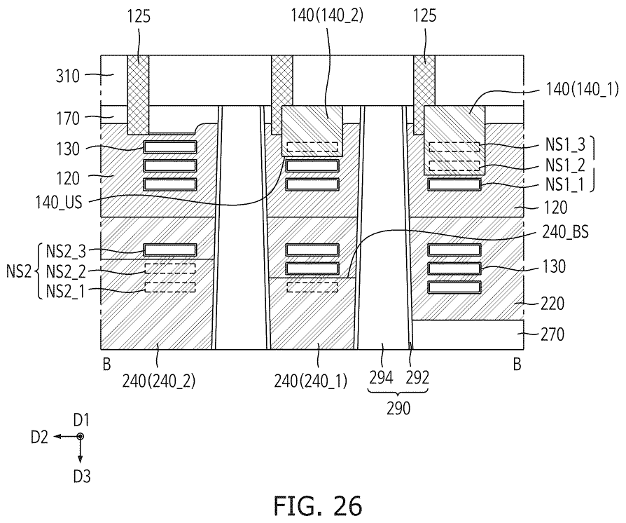

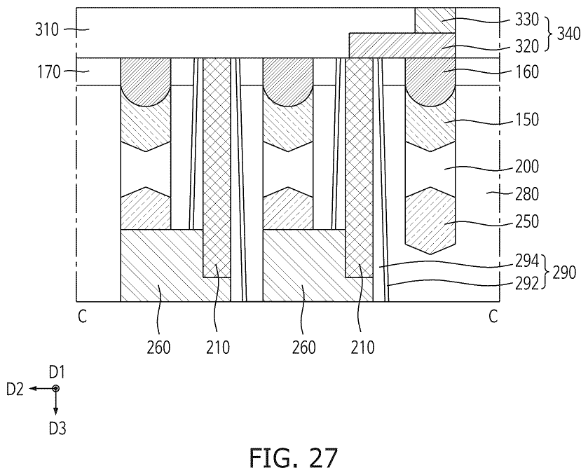

Referring to FIGS. 26 and 27, the lower wiring structure 340 and the lower gate contact 125 may be formed.

Specifically, the lower wiring insulating layer 310 and the lower wiring structure 340 may be formed on the lower capping pattern 170. The lower wiring structure 340 may be disposed in the lower wiring insulating layer 310. The lower wiring structure 340 may include a line wiring 320 and a lower via 330. The lower gate contact 125 may penetrate the lower insulating layer 310 and the lower capping pattern 170, and may be disposed on the lower gate electrode 120.

Although certain embodiments have been described with reference to the accompanying drawings, those of ordinary skill in the art to which the present disclosure pertains will understand that the present disclosure may be implemented in other specific forms without changing its technical idea or described features. Therefore, it should be understood that the embodiments described above are illustrative and non-limiting in all respects and any modifications thereto are intended to be encompassed within the scope of the appended claims.

What is claimed is

1. A semiconductor device comprising:
a plurality of lower sheet patterns spaced apart from each other in a first direction;
a lower gate electrode surrounding the plurality of lower sheet patterns and extending in a second direction intersecting with the first direction;
a plurality of upper sheet patterns disposed on the lower gate electrode and spaced apart from each other in the first direction;
an upper gate electrode disposed on the lower gate electrode and surrounding the plurality of upper sheet patterns, the upper gate electrode extending in the second direction; and
an upper isolation layer penetrating an upper surface of the upper gate electrode and extending in the first direction,
wherein the upper isolation layer penetrates at least a portion of the plurality of upper sheet patterns.

2. The semiconductor device according to claim 1, wherein the upper isolation layer is spaced apart from the lower gate electrode in the first direction.

3. The semiconductor device according to claim 1, further comprising a lower isolation layer penetrating a lower surface of the lower gate electrode and extending in the first direction,
wherein the lower isolation layer penetrates at least a portion of the plurality of lower sheet patterns.

4. The semiconductor device according to claim 3, wherein the upper isolation layer overlaps the lower isolation layer in the first direction.

5. The semiconductor device according to claim 1, wherein a width of the upper isolation layer in the second direction is greater than a width of each of the plurality of upper sheet patterns in the second direction.

6. The semiconductor device according to claim 1, wherein a lower surface of the upper isolation layer is disposed on the upper gate electrode and comprises a curved surface.

7. The semiconductor device according to claim 1, wherein the upper isolation layer penetrates all of the plurality of upper sheet patterns, and a portion of the upper gate electrode is disposed between the upper isolation layer and the lower gate electrode.

8. The semiconductor device according to claim 1, wherein a width of the upper isolation layer in a third direction is less than a width of each of the plurality of upper sheet patterns in the third direction, the third direction intersecting with each of the first direction and the second direction.

9. The semiconductor device according to claim 1, further comprising a gate insulating layer between the plurality of upper sheet patterns and the upper gate electrode, and between the plurality of lower sheet patterns and the lower gate electrode.

10. The semiconductor device according to claim 9, wherein the upper isolation layer penetrates a portion of the gate insulating layer.

11. The semiconductor device according to claim 1, wherein:
an uppermost upper sheet pattern of the plurality of upper sheet patterns comprises a first portion and a second portion,
the upper isolation layer is disposed between the first portion and the second portion, and
the first portion of the uppermost upper sheet pattern is spaced apart from the second portion in a third direction that intersects each of the first direction and the second direction.

12. A semiconductor device comprising:
a lower wiring insulating layer;
a lower wiring structure in the lower wiring insulating layer;
a plurality of lower sheet patterns disposed on the lower wiring insulating layer and spaced apart from each other in a first direction;
a lower gate electrode surrounding the plurality of lower sheet patterns and extending in a second direction intersecting the first direction;
a lower source/drain pattern on at least one side of the plurality of lower sheet patterns;
a lower isolation layer on the lower wiring insulating layer, the lower isolation layer penetrating a lower surface of the lower gate electrode and extending in the first direction;
a plurality of upper sheet patterns disposed on the lower gate electrode and spaced apart from each other in the first direction;
an upper gate electrode on the lower gate electrode, the upper gate electrode surrounding the plurality of upper sheet patterns and extending in the second direction;
an upper source/drain pattern on at least one side of the plurality of upper sheet patterns; and
an upper isolation layer penetrating an upper surface of the upper gate electrode and extending in the first direction,
wherein the lower isolation layer penetrates at least a portion of the plurality of lower sheet patterns, and
wherein the upper isolation layer penetrates at least a portion of the plurality of upper sheet patterns.

13. The semiconductor device according to claim 12, further comprising a gate separation structure extending a third direction and separating the upper gate electrode and the lower gate electrode, the third direction intersecting each of the first direction and the second direction.

14. The semiconductor device according to claim 13, further comprising:
a through via disposed in the gate separation structure and extending in the first direction; and
a lower source/drain contact on the lower source/drain pattern,
wherein the lower wiring structure is connected to the through via and the lower source/drain contact.

15. The semiconductor device according to claim 12, further comprising a gate capping pattern on the upper surface of the upper gate electrode,
wherein the upper isolation layer penetrates the gate capping pattern.

16. The semiconductor device according to claim 12, further comprising a lower gate contact disposed on the lower gate electrode and penetrating the lower wiring insulating layer,
wherein the lower gate contact is in contact with the lower isolation layer and the lower gate electrode.

17. The semiconductor device according to claim 12, further comprising a lower gate contact disposed on the lower gate electrode and penetrating the lower wiring insulating layer,
wherein the lower gate contact is spaced apart from the lower isolation layer in the second direction.

18. The semiconductor device according to claim 12, wherein a width of the upper isolation layer in the second direction decreases as distance from an upper surface of the upper isolation layer increases, and
a width of the lower isolation layer in the second direction decreases as distance from a lower surface of the lower isolation layer increases.

19. The semiconductor device according to claim 12, wherein a width of the upper isolation layer in the second direction is greater than a width of each of the plurality of upper sheet patterns in the second direction, and
a width of the lower isolation layer in the second direction is greater than a width of each of the plurality of lower sheet patterns in the second direction.

20. A semiconductor device comprising:
a lower wiring insulating layer;
a lower wiring structure in the lower wiring insulating layer;
a plurality of lower sheet patterns disposed on the lower wiring insulating layer and spaced apart from each other in a first direction;
a lower gate electrode surrounding the plurality of lower sheet patterns and extending in a second direction intersecting the first direction;
a lower gate contact disposed on the lower gate electrode and penetrating the lower wiring insulating layer;
a lower source/drain pattern on at least one side of the plurality of lower sheet patterns;
a lower isolation layer on the lower wiring insulating layer, the lower isolation layer penetrating a lower surface of the lower gate electrode and extending in the first direction;
a plurality of upper sheet patterns disposed on the lower gate electrode and spaced apart from each other in the first direction;
an upper gate electrode on the lower gate electrode, the upper gate electrode surrounding the plurality of upper sheet patterns and extending in the second direction;
a gate capping pattern on an upper surface of the upper gate electrode;
an upper source/drain pattern on at least one side of the plurality of upper sheet patterns; and
an upper isolation layer penetrating the upper surface of the upper gate electrode and extending in the first direction,
wherein the lower isolation layer penetrates at least a portion of the plurality of lower sheet patterns,
wherein the upper isolation layer penetrates the gate capping pattern and at least a portion of the plurality of upper sheet patterns, and
wherein the upper isolation layer overlaps the lower isolation layer in the first direction.
